(19) United States
(12) Patent Application Publication
(10) Pub. No.: US 2003/0111716 A1
(43) Pub. Date: Jun. 19, 2003

(54) WIREBONDED MULTICHIP MODULE

(76) Inventor: Kazuaki Ano, Hayami-gun (JP)

Correspondence Address: Mike Skrehot, Texas Instruments Incorporated, M/S 3999, P. O. Box 655474, Dallas, TX, 75265, US

(21) Appl. No.: 10/017,737

(22) Filed: Dec. 14, 2001

(51) Int. Cl. H01L 23/02

(52) U.S. Cl. 257/678

(57) ABSTRACT

The present invention provides a multichip arrangement and method of arranging multiple chips including at least a first chip (10) and second chip (30). The first chip (10) having opposing top and bottom surfaces in which bonding pads are located on a perimeter of the top surface. The bonding pads are operable for bonding bond wires for coupling the multichip arrangement to a circuit board (40), for example. The second chip (30) also has opposing top and bottom surfaces with bonding pads located on a perimeter of the top surface. In one embodiment an attach layer (220) having an area equal to an area of the second chip bottom surface is applied to the second chip bottom surface. The second chip (30) is coupled to the first chip (10) via the attach layer (220). The attach layer (220) has a thickness to provide electrical disconnection of the first chip wire bonds and the second chip (30). The attach layer (220) is a thermosetting material which is pliable when heated for coupling the first (10) and second chip (30) such that the thermosetting material conforms to the first chip wire bond when the second chip (30) is coupled to the first chip (10). In another embodiment, an insulation layer (230) is applied to the second chip bottom surface prior to application of the attach layer (220) in which the attach (220) layer and the insulation layer (230) are cooperable to provide electrical disconnection of the first chip wire bonds and the second chip.

### BACKGROUND OF THE INVENTION

1. Technical Field of the Invention

The present invention relates to multiple chip packaging and, more particularly, to wire bonded stacked chip arrangements.

2. Description of Related Art

As advancement requires integrated circuit density to increase, innovative packaging techniques must be developed to minimize size while protecting electrical connections. Since single packaged IC chips consume relatively large areas of mounting surface, multiple chip packaging has been developed for applications where the size of the assembly is an important consideration. Further, as density increases other improvements are realized such as reduced overall assembly weight and improved noise characteristics, for example. Typical stacked IC packages combine a number of individual IC chips attached to each other in a stacked arrangement such that the mounting surface area is limited to the area of one of the individual IC chips.

Referring now to FIG. 1 there is illustrated a conventional multiple stacked IC chip. Typically, multiple stacked IC chips consist of a lower chip 10 having a bottom and top surface and a upper chip 30 having a bottom and top surface. The bottom of the upper chip 30 is stacked atop the top of the lower chip 10 in which the bottom of the lower chip 10 is connected to the circuit board 40. The chips have bonding pads located on the outside perimeter of each respective top surface. IC chips are generally packaged in encapsulating materials 50 with leads for coupling to circuit board 40. Electrical connection of the stacked chips to the circuit board 40 can be performed by wire bonding or other similar techniques. The two chips are attached together via a spacer 20 disposed on the lower chip 10 prior to applying the upper chip 30 to the stack. Conventionally, the spacer 20 only contacts an inner portion of the lower chip's top surface and the upper chip's bottom surface and does not contact the outside perimeter. Thus, the lower chip bonding pads and wire loops have no contact with the spacer 20.

The spacer 20 must be of a thickness that provides a distance between the chips to prevent damage and interference from the upper chip to the lower chip wire loop. This distance must be at least that of the wire loop height plus an additional safety distance. The safety distance is to protect the wire loop not only from physical damage to the wire loop during attachment of the upper chip, but also from electrical interference. Conventionally, the safety distance is increased to provide a larger processing window which helps reduce reliability problems of the bonding wires. Typically, for production purposes, conventional spacers 20 have a height of 200 microns. Improving reliability with this approach is at the expense of increasing the overall height of the chip. This becomes increasingly important as the number of chips on the stack is increased.

### SUMMARY OF THE INVENTION

The present invention achieves technical advantages as a multichip arrangement and method of arranging multiple chips including at least a first and second chip. The first chip having opposing top and bottom surfaces in which bonding pads are located on a perimeter of the top surface. The bonding pads are operable for bonding bond wires for coupling the multichip arrangement to a circuit board, for example. The second chip also has opposing top and bottom surfaces with bonding pads located on a perimeter of the top surface. In one embodiment an attach layer having an area equal to an area of the second chip bottom surface is applied to the second chip bottom surface. The second chip is coupled to the first chip via the attach layer. The attach layer has a thickness to provide electrical disconnection of the first chip wire bonds and the second chip. The attach layer is a thermosetting material which is pliable when heated for coupling the first and second chip such that the thermosetting material conforms to the first chip wire bond when the second chip is coupled to the first chip. In another embodiment, an insulation layer is applied to the second chip bottom surface prior to application of the attach layer in which the attach layer and the insulation layer are cooperable to provide electrical disconnection of the first chip wire bonds and the second chip.

### BRIEF DESCRIPTION OF THE DRAWINGS

For a more complete understanding of the present invention, reference is made to the following detailed description taken in conjunction with the accompanying drawings wherein:

FIG. 1 illustrates a conventional multiple stacked IC chip;

FIG. 2 illustrates a multiple stacked IC chip arrangement in accordance with an exemplary embodiment of the present invention;

FIG. 3 illustrates a multiple stacked IC chip arrangement in accordance with another exemplary embodiment of the present invention; and

FIG. 4 shows a top view of the stacked arrangement illustrated in FIGS. 2 and 3.

### DETAILED DESCRIPTION OF THE INVENTION

The numerous innovative teachings of the present application will be described with particular reference to the presently preferred exemplary embodiments. However, it should be understood that this class of embodiments provides only a few examples of the many advantageous uses and innovative teachings herein. In general, statements made in the specification of the present application do not necessarily delimit any of the various claimed inventions. Moreover, some statements may apply to some inventive features, but not to others.

Throughout the drawings, it is noted that the same reference numerals or letters will be used to designate like or equivalent elements having the same function. Detailed descriptions of known functions and constructions unnecessarily obscuring the subject matter of the present invention have been omitted for clarity.

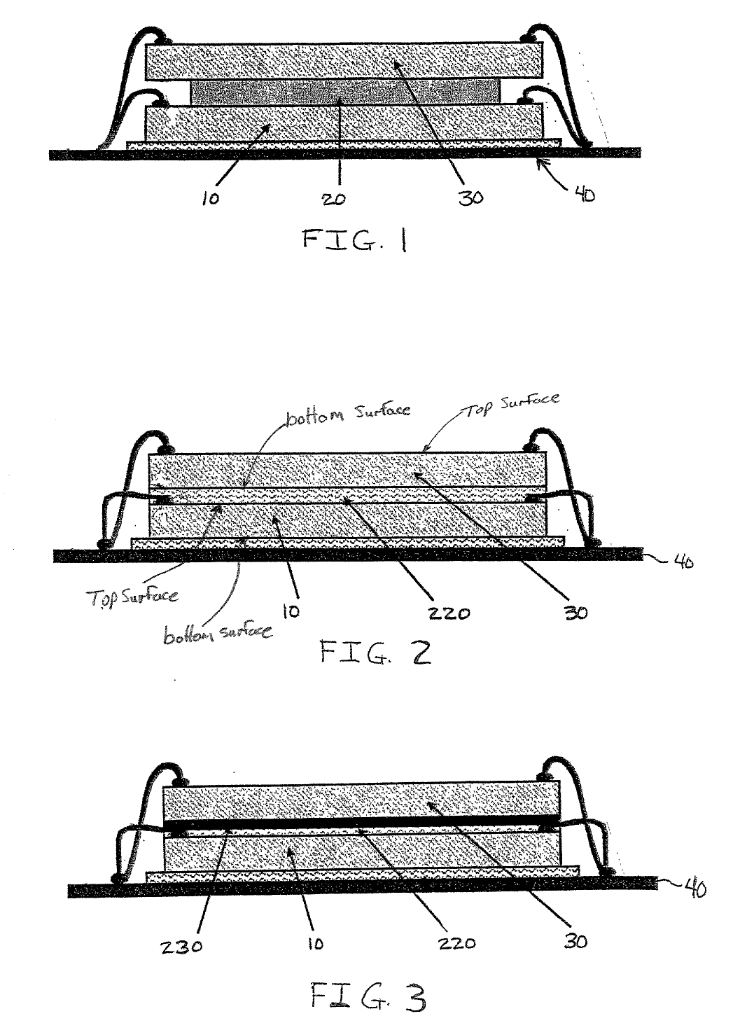

Referring now to FIG. 2 there is illustrated a multiple stacked IC chip arrangement in accordance with an exemplary embodiment of the present invention. In this embodiment, the chip module includes at least a lower chip 10 having a bottom and top surface and a upper chip 30 having a bottom and top surface. The bottom of the upper chip 30 is stacked atop the top of the lower chip 10 in which the bottom of the lower chip 10 is connectable to a circuit board 40 or other substrate. Note that the upper chip 30 is stacked directly on top of the lower chip 10 (such that there is no overhang) and that the chips are approximately the same size. FIG. 4 shows the top view of the stacked arrangement illustrated in FIG. 2. Note that the bonding pads of the lower chip 10 are completely covered by the upper chip 30 and that the lower chip 10 does not extend out beyond the perimeter of the upper chip 30.

The chips (10 and 30) have bonding pads located on the outside perimeter of each respective top surface. Electrical connection of the stacked chip module to the circuit board 40 can be performed by wire bonding or other similar techniques. The two chips are advantageously attached together via a die attach material 220 applied on the bottom surface of the upper chip 30 prior to applying the upper chip 30 to the stack. A layer of the die attach material 220 is applied across the entire upper chip bottom surface such that when the upper chip 30 is place on the stack the bonding pads of the lower chip 10 are completely covered.

The die attach material 220 is a thermosetting material which become soft when heated and rigid when subsequently cooled. Further, in at least one embodiment, the thermosetting material is a semi conducting material. Prior to pressing the upper chip 30 onto the lower chip 10, the die attach material 220 is heated to become pliable. Subsequently, the upper chip 30 is pressed onto the lower chip 10 and the die attach material 220 conforms around the bonding pads of the lower chip 10. When cooled, the die attach material 220 becomes rigid and attachment is complete. This process can be repeated for each of a plurality of chips. The thickness of the die attach material 220 is selected such that there is electrical disconnection from the upper chip 30 and the wire bond of the lower chip 10 when the upper chip 30 is pressed to its final position. For example, with a semi conducting material, there should be at least a 10 μm gap between the wire bond of the lower chip 10 and the upper chip 30 to provide electrical disconnection. The chip module can obviously include more that two chips by repeating the above-described process for each successive chip.

The die attach thickness can vary depending on the bonding method used on the lower chip 10. For example, where ball bonding is first applied to the chip (as shown in FIG. 1) the wire loop is greater than if the bonding is reversed and the ball bonding is first applied to the circuit board or substrate. For wire bonding of the type shown in FIG. 1, the die attach thickness is approximately 150 μm to approximately 200 μm. For the wire bonding of the type shown in FIGS. 2, the die attach thickness is approximately 70 μm to approximately 100 μm.

The present approach not only advantageously protects the wire bond of the lower chip 10 during attachment, but also encapsulates the wire bond to protect from future possible physical damage. This approach can also reduce the production distance between stacked chips and the overall height of the chip module.

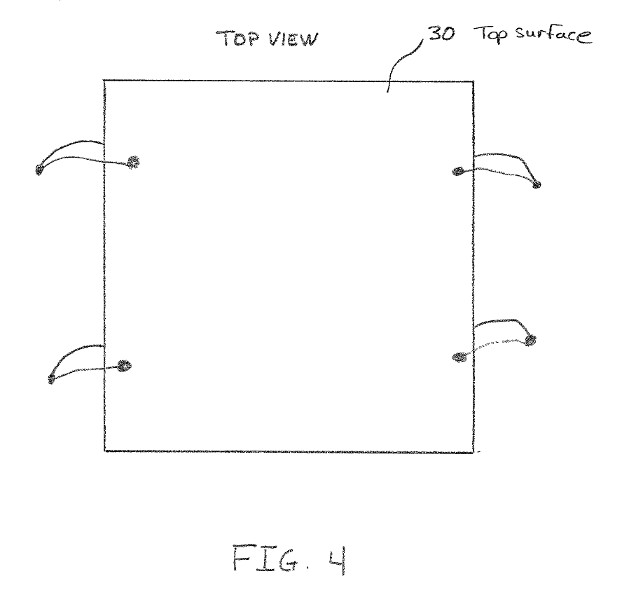

Referring now to FIG. 3 there is illustrated a multiple stacked IC chip arrangement in accordance with another exemplary embodiment of the present invention. In this embodiment, the chip module includes at least a lower chip 10 having a bottom and top surface and a upper chip 30 having a bottom and top surface. The bottom of the upper chip 30 is stacked atop the top of the lower chip 10 in which the bottom of the lower chip 10 is connectable to a circuit board 40 or other substrate. Note that the upper chip 30 is stacked directly on top of the lower chip 10 (such that there is no overhang) and that the chips are approximately the same size, as shown in FIG. 4.

The difference between this embodiment and that shown in FIG. 2 is the addition of a layer of an insulation material 230 applied to the bottom surface of the upper chip 30 prior to the application of the die attach material 220. The insulation material 230 is applied across the entire upper chip bottom surface. Similar to that described above, a layer of the thermosetting die attach material 220 is then applied across the entire upper chip bottom surface area such that when the upper chip 30 is place on the stack the bonding pads of the lower chip 10 are completely covered.

Prior to pressing the upper chip 30 onto the lower chip 10, the die attach material 220 is heated to become pliable. Subsequently, the upper chip 30 is pressed onto the lower chip 10 and the die attach material 220 conforms around the bonding pads of the lower chip 10. After a period of time for cooling, the die attach material 220 becomes rigid. The thickness of the insulation material layer and the die attach material is cooperatively selected such that there is electrical disconnection from the upper chip 30 and the wire bond on the lower chip 10 when the upper chip 30 is pressed to its final position and the final distance between the stacked chips is minimalized.

In one embodiment, the insulation material 230 is an inorganic material, such as SiO2 (silicon dioxide), with a thickness of approximately 1 μm. In another embodiment, the insulation material 230 is an organic material, such as epoxy, with a thickness of approximately 5 μm to approximately 100 μm. Regardless of the thickness of the insulation layer 230, the thickness of the die attach layer 220 is preferably approximately 70 μm to 200 μm depending on the type of bonding used on the lower chip 10. The thickness of the die attach layer 220 is less in the embodiment illustrated in FIG. 3 because an electrical disconnection gap is provided by the insulation layer.

Although a preferred embodiment of the method and system of the present invention has been illustrated in the accompanied drawings and described in the foregoing Detailed Description, it is understood that the invention is not limited to the embodiments disclosed, but is capable of numerous rearrangements, modifications, and substitutions without departing from the spirit of the invention as set forth and defined by the following claims.

What is claimed is:

1. A multichip module comprising:
a first chip having opposing top and bottom surfaces and having bonding pads located on a perimeter of said top surface, each of said bonding pads operable for bonding a wire;
a second chip having opposing top and bottom surfaces and having bonding pads located on a perimeter of said top surface, each of said bonding pads operable for bonding a wire;
a first attach layer having an area equal to an area of said second chip bottom surface for coupling said first chip and said second chip, said first attach layer having a thickness to provide electrical disconnection of said first chip wire bonds and said second chip, said first attach layer is applied to said second chip bottom surface prior to coupling said first chip and said second chip.

2. The multichip module of claim 1, wherein said electrical disconnection is provided as a gap between said first chip wire bonds and said second chip, and wherein said gap is approximately 10 μm.

3. The multichip module of claim 1, wherein said first attach layer is a thermosetting material, wherein said thermosetting material is pliable for coupling said first chip and said second chip such that said thermosetting material conforms to said first chip wire bond.

4. The multichip module of claim 1, wherein said first chip top and bottom surfaces and said second chip top and bottom surfaces have equal areas.

5. The multichip module of claim 1, wherein said first chip and said second chip have a stacked arrangement such that said first chip bonding pads are covered from above by said second chip.

6. The multichip module of claim 1 further including a second attach layer having an area equal to said second chip bottom surface area and disposed between said first attach layer and said second chip bottom surface, said second attach layer being an insulating material having a thickness cooperable with said first attach layer to provide electrical disconnection of said first chip wire bonds and said second chip.

7. The multichip module of claim 6, wherein said first attach layer is a thermosetting material, wherein said thermosetting material is pliable for coupling said first chip and said second chip such that said thermosetting material conforms to said first chip wire bond and said second attach layer is silicon dioxide.

8. The multichip module of claim 6, wherein said electrical disconnection is provided as a gap between said first chip wire bonds and said second chip, and wherein said gap is approximately equal to said second attach layer thickness.

9. The multichip module of claim 6, wherein said second attach layer thickness is approximately 1 μm.

10. The multichip module of claim 6, wherein said first chip top and bottom surfaces and said second chip top and bottom surfaces have equal areas, and wherein said first and second chips are stacked such that said first chip bonding pads are covered from above by said second chip.

11. A method of arranging a plurality of integrated chips in a multichip module, comprising:
providing a first chip having opposing top and bottom surfaces and having bonding pads located on a perimeter of said top surface;
bonding a wire to each of said bonding pads;
providing a second chip having opposing top and bottom surfaces and having bonding pads located on a perimeter of said top surface;
applying a first attach layer having an area equal to an area of said second chip bottom surface for coupling said first chip and said second chip, said first attach layer having a thickness to provide electrical disconnection of said first chip wire bonds and said second chip; and
coupling said first chip and second chip, wherein said second chip bottom surface is coupled to said first chip top surface via said first attach layer.

12. The method of claim 11, wherein said first attach layer is applied to said second chip bottom surface prior to coupling said first chip and said second chip.

13. The method of claim 11, wherein said first attach layer is a thermosetting material, wherein said thermosetting material is pliable for coupling said first chip and said second chip such that said thermosetting material conforms to said first chip wire bond.

14. The method of claim 11 further including providing said first chip top and bottom surfaces and said second chip top and bottom surfaces with equal areas.

15. The method of claim 11 further including coupling said first chip and said second chip to provide a stacked arrangement such that said first chip bonding pads are covered from above by said second chip.

16. The method of claim 11 further providing a second attach layer having an area equal to said second chip bottom surface area and disposed between said first attach layer and said second chip bottom surface, said second attach layer being an insulating material having a thickness cooperable with said first attach layer to provide electrical disconnection of said first chip wire bonds and said second chip.

17. The method of claim 16, wherein said electrical disconnection is provided as a gap between said first chip wire bonds and said second chip, and wherein said gap is approximately equal to said second attach layer thickness.

18. The method of claim 17, wherein said second attach layer thickness is approximately 1 μm.

19. The method of claim 16, wherein said first attach layer is a thermosetting material, wherein said thermosetting material is pliable for coupling said first chip and said second chip such that said thermosetting material conforms to said first chip wire bond.

20. The method of claim 16 further including providing said first chip top and bottom surfaces and said second chip top and bottom surfaces with equal areas and coupling said first chip and said second chip to provide a stacked arrangement such that said first chip bonding pads are covered from above by said second chip.
